(19) United States
(12) Patent Application Publication
(10) Pub. No.: US 2017/0047847 A1
(43) Pub. Date: Feb. 16, 2017

(54) Stabilized Power Supply Utilizing Resonance Circuit Driven by Carrier Modulated Both in Frequency And Amplitude

(71) Applicant: Masatosi Imori, Bunkyo-ku (JP)

(72) Inventor: Masatosi Imori, Bunkyo-ku (JP)

(21) Appl. No.: 15/201,730

(22) Filed: Jul. 5, 2016

(30) Foreign Application Priority Data
Aug. 10, 2015 (JP) 2015-200007

(51) Int. Cl. H02M 3/335; H02M 1/08; H03K 17/687; H03K 7/08; H03K 5/01

(52) U.S. Cl. CPC H02M 3/33507; H03K 7/08; H03K 5/01; H03K 17/6871; H02M 1/08; H03K 2217/0045; H03K 2217/009; H02M 2001/0009

(57) ABSTRACT

With the stabilized direct-current power supply utilizing the resonance circuit driven by the carrier, the output of the resonance circuit is rectified and smoothed to produce the output voltage of the power supply. The output voltage of the power supply being fixed, the amplitude and the frequency of the carrier driving the resonance circuit is mutually related.

There is an optimal frequency of the carrier where the power supply becomes efficient. The optimal frequency depends on the magnitude of the load connected to the output of the power supply. So the power supply feeds the output current to the amplitude on the basis of the mutual relation so as to makes the frequency of the carrier follow the optimal frequency.

Implementation of the priactical PWM controller provided with both the frequency modulation input and the amplitude modulation input is configured. The error voltage, which is the voltage difference between the output voltage and the reference voltage of the power supply, is fed back to both the frequency and the amplitude of the carrier. Integral of the error voltage is fed back to the frequency through the frequency modulation input of the PWM controller, which stabilizes the feedback to the frequency. Proportional of the error voltage and the output current of the power supply is fed back to the amplitude through the amplitude modulation input. The output current, considered to be differential of the output voltage and then the error voltage, sets the base line of the amplitude which is modulated by the proportional of the error voltage. The mutual rekation control the base line of the amplitude so that the frequency of the carrier can track the optimal frequency.

### TECHNICAL FIELD

The invention is concerning the power supply, where the output is produced by the resonance circuit and stabilized against a wide range of the load.

### BACKGROUND ART

There is such a stabilized power supply that the output of the resonance circuit driven by a fixed-frequency carrier is rectified and smoothed to produce the power supply output the feedback of which to the amplitude of the carrier improves output regulation. There is a stabilized power supply where, the Q value of the resonance circuit being high, a fixed amplitude carrier drives the resonance circuit, and feeding back the output of the power supply, generated by rectifying and smoothing the output of the resonance circuit, to the frequency of the carrier improves output regulation,

As an example of a power supply utilizing a resonance circuit for voltage generation, there is a direct-current voltage power supply where a piezoelectric transformer works as a resonance circuit. In the case of stabilizing the output voltage by using the frequency dependency of the resonance, the output voltage is fed back to the frequency of the carrier driving the resonance circuit. The frequency of the carrier for realizing a specified output voltage varies over a wide range, depending on the load. The frequency of the carrier corresponding to the light load is away from the resonance frequency, which makes the efficiency of the power supply low.

[Patent Citation 1] Japanese Examined Patent Application Publication No. 4053255

[Patent Citation 2] Japanese Examined Patent Application Publication No. 4268013

[Patent Citation 3] Japanese Examined Patent Application Publication No. 5412651

[Patent Citation 4] Japanese Unexamined Patent Application Publication No. 2008-306775

[Patent Citation 5] Japanese Examined Patent Application Publication No. 5555949

[Patent Citation 6] Japanese Unexamined Patent Application Publication No. 2010-229540

[Patent Citation 7] Japanese Examined Patent Application Publication No. 5659438

[Patent Citation 8] Japanese Examined Patent Application Publication No. 5282197

[Patent Citation 9] M. Imori, PCT/JP2007/000477, Mar. 5, 2007.

[Patent Citation 10] M. Imori, U.S. Pat. No.: 8,837,172 B2

Patent document 1 provides configuration of a simple circuit for a direct current high voltage power supply supplying stabilized high voltage with good efficiency. Employing a piezoelectric transformer instead of an electromagnetic one for high voltage generation improves efficiency and utilizing the frequency dependence of the resonance of the piezoelectric transformer to stabilize the high voltage simplifies the circuit of the power supply and reduces the number of the components.

Patent Document 2 concerns the feedback to stabilize the output voltage of a direct-current high-voltage power supply, where implementing additional feedback with a small delay together with the feedback with a large delay associated with the generation of the high voltage improves the accuracy and the speed of response of the output.

Patent Document 3 provides configuration of the feedback to stabilized the output of a direct current high-voltage power supply and circuit coefficients. Stability of feeding back the output voltage to the frequency of the carrier requires to provide the transfer function transferring the output voltage to the frequency of the carrier with a pole located in the neighborhood of the origin.

Patent Document 4 provides configuration of the feedback to stabilize the output of a direct current high voltage power supply and circuit coefficients, where the transfer function feeding back the output voltage to the frequency of the carrier does not hold a pole located in the neighborhood of the origin. Patent Document 9 was a PCT international application based on Patent Document 3 and 4.

Patent Documents 6 and 8 provides configuration of the feedback to stabilize the output of a direct current high voltage power supply and circuit coefficients, where the feedback utilizes frequency and amplitude dependence of the resonance characteristics. Output error in voltage is fed back to the both the frequency and the amplitude of the carrier driving the resonance circuit. Patent document 8 was a national phase of Patent Document 10.

Patent document 7 concerns stabilized power supply that generates the output of the power supply by rectifying the output of the resonance circuit. Feeding back the output of the power supply to both the frequency and the amplitude of the carrier driving the resonance circuit stabilizes the output of the power supply. Furthermore, feeding back the output current of the power supply to the amplitude in the case of a voltage power supply keeps the frequency varying by the change of magnitude in load within the range optimum in efficiency. Similarly feeding back the output voltage of the power supply to the amplitude in the case of a current power supply keeps the frequency varying by the change of magnitude in load within the range optimum in efficiency.

### SUMMARY OF INVENTION

### Technical Problem

Concerning the power supply where carrier drives the resonance circuit and rectifying the output of the resonance circuit generates the output of the power supply, the frequency optimum in efficiency varies with the load. The frequency of the carrier cannot follow the optimal frequency in the case that the frequency of the carrier is fixed. Introducing a practical pulse-width modulation (hereafter abbreviated to PWM) controller that modulates the frequency and the amplitude of the carrier so that the carrier of the optimal frequency can drive the resonance circuit, we show the configuration of the stabilized power supply and circuit coefficients.

### Solution to Problem

Input in Dead Time

VCO is an abbreviation for voltage-controlled frequency generator. The VCO varies the output frequency according to the input voltage. In most implementations of the VCO, the input voltage is converted into a current to charge a capacitor. The current being charging the capacitor to a prescribed voltage causes the forced discharge, thus resetting the voltage of the capacitor and making the current charge the capacitor, which repeats the charge and the reset of the capacitor. The frequency of the reset is the output frequency of the VCO where the output frequency is dependent on the current and then the input voltage.

Discharging the charge of the capacitor is performed by short-circuiting the capacitor to the ground. Input voltage during the short-circuiting can not charge the capacitor, which means that the output frequency cannot reflect the input voltage during the period of the short-circuiting. We understood that there is a dead time during which the input voltage is not reflected in the output frequency and that the dead time is almost periodic.

Pulse Width Modulation Controller

Modulating the amplitude of the carrier driving the resonance circuit consists of a full bridge of FETs to generate carrier and a PWM controller to modulate the amplitude by controlling the pulse width during which the FETS are turned on. A PWM controller is provided with an amplitude modulation (hereafter abbreviated to AM) input. The controller operates based on the AM input, producing gate pulses with varying pulse width. The output of the PWM controller is the gate pulses which controls the amplitude of the carrier.

The output of the power supply is the direct current voltage produced by rectifying the output of the resonance circuit, and the reference voltage is the predetermined voltage of the output. The voltage error between the output and the reference voltages is led to the AM input. The PWM controller controls the gate pulses so as to reduce the voltage error.

Reset Pulses and Sawtooth Pulses

The frequency of the carrier in most PWM controllers is fixed. The controller has a constant current source and a capacitor that is charged by the current source. The capacitor charged to a predetermined voltage, is forcibly discharged to the ground, repeating resetting the voltage of the capacitor. The frequency of the reset pulse is fixed. The voltage spanning the capacitor is sawtooth voltage synchronized with the reset pulse, where the sawtooth voltage is used to generate the gate pulse. The sawtooth voltage compared with the voltage at the AM input controls the pulse widrh of the gate pulses.

Since comparing the sawtooth voltage with the voltage at the AM input determines pulse width of the gate pulses and then turn-on and turn-off of the FETs, the sawtooth wave is required to provide excellent linearity. In the case that the frequency of the reset pulse and then the frequency of the carrier is fixed, a sawtooth wave with excellent linearity can be generated by charging the capacitor with a constant current source.

PWM Controller Modulating Carrier in Frequency

In the case that the frequency of the carrier is fixed, the sawtooth voltage is compared with the voltage at the AM input within each cycle of the frequency, which controls the gate pulses so as to reduce the voltage error, turning on and off the FETs. The comparison within each cycle is the case with the variable frequency of the carrier. Namely, the sawtooth voltage is compared with the voltage at the AM input within each cycle of the variable frequency to control turn-on and turn-off of FETs.

While the AM input is kept constant, the shift of the frequency may cause the shift of the output voltage even though comparing the sawtooth voltage with the AM input within each cycle. Assuming that the resonance circuit, the driver circuit, and the rectifying and smoothing circuit are ideal without frequency dependence, it may be possible that the output voltage does not depend on the frequency of the carrier while the AM input is fixed. Practically the circuits show frequency dependence. So by choosing the range of the frequency of the carrier higher than the resonance frequency of the resonance circuit, it will be possible to expand the range of the frequency showing the monotonicity of the response of the output voltage against the AM input and the frequency of the carrier.

Implementation of PWM Conyroller

In the case that the frequency of the carrier is fixed, charging the capacitor with a constant current source produces simultaneously the reset pulse and a sawtooth voltage in synchronization. In the case that the frequency of the carrier is variable, the PWM controller is provided with a frequency modulation (hereafter abbreviated to FM) input for controlling the frequency of the carrier. Charging a capacitor with the current converted from the voltage applied to the FM input does not produce the sawtooth voltage with an excellent linearity because a shift of the FM input is reflected in the linearity.

For the generation of the sawtooth voltage with an excellent linearity, it is necessary to charge a capacitor with a constant current within each cycle, while the constant current may vary cycle to cycle in magnitude. Then the voltage applied to the FM input is sampled by the reset pulse and the sampled voltage is converted to the current charging the capacitor. The capacitor charged to the prescribed voltage generates the reset pulse by which the capacitor discharges to the ground, repeating the charging and the discharging. Thus the capacitor is charged with a constant current within each cycle generating the sawtooth voltage with an excellent linearity synchronized with the reset pulse.

Control Input Out of Use

In the case of the PWM controller for variable frequency, only the FM input sampled by the reset pulse affects the cycle of the controller. Thus for the most period of the cycle, the FM input is out of use. In many cases, the implementation of the circuit where the cyclic operation is controlled by an external signal accompanies the period where the external signal is out of use in each cycle.

In most cases, the practical PWM controller modulating both the frequency and the amplitude of the carrier does not change the frequency continuously but shifts the frequency at discrete points of time. For example, the shift of the FM input just after the reset pulse is sampled by the next reset pulse. Thus, the gate pulses follow the FM input with a delay.

Ideal PWM Controller

The output of the PWM controller modulating the frequency and the amplitude is the gate pulses turning on and off the FETs. The gate pulse of the practical PWM controller depends on the FM input at discrete points of time. An ideal PWM controller could make the gate pulses follow the FM input without delay. The PWM controller is closer to the ideal as smaller is the delay.

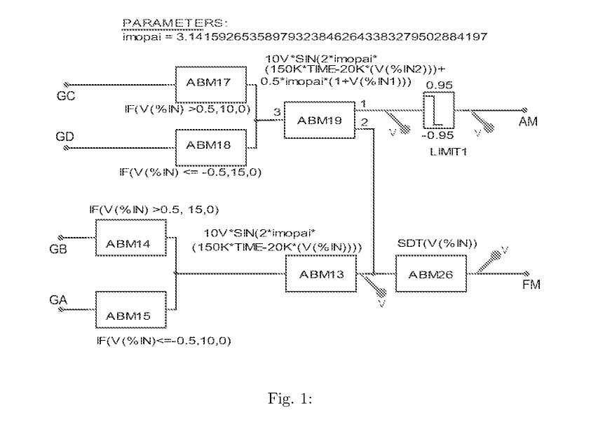

In the above sense, the PWM controller shown in FIG. 1 is close to the ideal whether the controller can be put to practical use or not, where the controller generates two sinusoidal waves the frequency of which is specified by the FM input. The AM input controls the phase shift of one to the other. The controller generates the gate pulses by comparing the two waves with the prescribed threshold. Even though it may be feasible to construct more idealistic controller, hereafter we call the PWM controller shown in FIG. 1 the ideal PWM controller.

Simulation

FIG. 1 shows the ideal PWM controller composed of such elements that can be simulated in a SPICE simulator. The ideal controller can be integrated into a circuit for simulation. The PWM controllers are commercially available, The SPICE model of some products are supplied by manufacturers.

The SPICE models being available, it is possible to simulate the power supply integrating the PWM controller. Compared with commercialised PWM controller, the ideal PWM controller is fast in simulation and simple in operation that facilitates theoretical investigations. The ideal PWM controller is capable of simulating the practical PWM controller with the period of out of use. To simulate the power supply integrating the ideal PWM controller is useful to understand the power supply using the practical PWM controller.

Stability of Feedback

We studied the stability of the power supply by repeating the simulation where the power supply integrates the ideal PWM controller. The ideal PWM controller has the FM input and the AM input. Let the transfer function transferring the voltage error between the output and the reference voltages to the FM input or rather the frequency of the carrier equal

$$\frac{E}{s} + A + Bs where E > 0 , A \geq 0 , and B \geq 0 , \qquad [ 1 ]$$

where the transger function is composed of a integral, a proportional and a differential parts, we studied the stability of the feedback implemented by the transfer function 1. It was show that the integral part stabilized the feedback.

In the case that the voltage error is not fed back to the amplitude and that the feedback of the voltage error to the frequency is composed of an integral part without the proportional and the differential parts, the output voltage is slow in response, and additional parts becomes necessary to improve the response. In the case that the voltage error is fed back to the amplitude in addition to the frequency, it is not yet clear that other than an integral part is necessary for the feedback to the frequency, namely the function 1. As is shown in Patent Document 10, the feedback of the voltage error to the amplitude includes the proportional part and the differential part with proper coefficients.

It can be considered that the integration of the output current approximates the output voltage. Then the feedback of the output current to the amplitude corresponds to the feedback of the voltage error in terms of the differential part. Feedback of neither the output voltage nor the output current to the amplitude implements feeding back the voltage error to the frequency in terms of an integral part.

The integral and the proportional parts of the voltage error are fed back as they are to the frequency and to the amplitude of the carrier respectively, and the differential part of the voltgae error takes the form of feeding back the output current to the amplitude. The above implementation of the feedback will be a method of realizing what is called PID control.

Ripples on the Output

As we apply theoretical investigations to an actual circuit, the characteristics of circuit elements may be different from the ones that we assume in the theoretical studies. From the viewpoint of feedback stability, the difference will reduce to the difference in the amplitude and the phase response against the frequency. The actual PWM controller samples the FM input almost periodically, and then the output of the controller is different from the one of the ideal PWM controller as the frequency comes close to the sampling frequency, The actual controller approximate the ideal one while the frequency is far less than the sampling one.

In the actual circuit, the ripples synchronized with the sampling are superimposed on the output of the power supply. The expression 1 is the transfer function transferring the voltage error to the FM input. In the actual PWM controller, assigning A=0 and B=0 in the expression limits the bandwidth of the transfer function far less than the sampling frequency, and then eliminates effects of the ripples.

In Patent Document 6, 8,and 10, we investigated the stability of feedback in the ideal PWM controller for variable frequency where the transfer function transferring the voltage error to the amplitude of the carrier, namely the transfer function transferring the voltage error to the AM input, is assumed to be [2]

G+H s where G>0, H≧0,

In the case that the output current of the power supply, thought to be a kind of the differential of the output voltage, is fed back to the AM input, the output current, taking the place of the differential part of the output voltage, may nullify the coefficient H in the expression 2. Assigning H=0 narrows the bandwidth of the feedback fed to the AM input.

In Patent Document 7, we studied the stability of feedback feeding back the output current of the power supply to the amplitude of the carrier. Feeding back the output current properly keeps the frequency of the carrier almost constant independently of the output current, namely the load of the power supply

Amplitude Modulation of PWM Controller

Feeding back the voltage error to the amplitude and the feeding back the output current to the amplitude are summed at the AM input of the PWM controller. Both of the feedback works in the same direction and the opposite direction. In the case that the feedback works in the opposite direction, it is necessary that the feedback of the voltage error is dominant over the feedback of the output current. In other words, G in the expression 2 needs to be selected so as to dominate the feedback of the output current.

Amplitude Modulation by Output Current

The output current of the power supply is supplied to an amplitude modulation circuit that converts the output current for the AM input. The conversion maintains the frequency of the carrier almost constant independently of the output current. Let fᵣ be the frequency kept almost constant, Iₒ be the output current and Vₙ be the reference voltage of the power supply.

We explain the conversion from the output current to the AM input. Let us consider a measuring apparatus composed of a driver circuit, a resonance circuit, and a rectifying and smoothing circuit, and a variable load, where the driver circuit includes a PWM controller the AM input of which is adjustable with a variable voltage source. A voltage at the FM input fixes the frequency at fᵣ. Thus, the carrier generated by the driver circuit is variable in the amplitude and fixed in frequency. The carrier drives the resonance circuit, and the output of the resonance circuit being rectified and smoothed, the rectifying and smoothing circuit applies its output to a load of a variable resistor or a current source.

Installing a fixed load in the apparatus, the direct current voltage spanning the load varies as the amplitude of the carrier changes. Then there exists such an amplitude at which the voltage spanning the load coincide with Vₙ. Then the voltage applied to the AM input realizing the amplitude is Vₘ for the AM input against Iₒ of the output current with the load.

In the measuring apparatus, scanning the amplitude plots the output voltage against the AM input for a fixed load. In voltage power supply, feeding back the voltage error to the frequency makes the frequency dependent on both the amplitude and the output current. Then the amplitude corresponding to the output current Iₒ brings the frequency toward fᵣ. Furthermore, the frequency stays in the neighborhood of fᵣ while the amplitude follows the output current.

Using the measuring apparatus based on Implementation 1, we plot the output voltage against the AM input, where the load is 1 Ω. From the plot, the AM input for the output voltage being 3 V is −160 mV. The reference voltage of the power supply is 3 V, and then the AM input for the output current of 3 A is −160 mV. The implementation of the power supply interpolares the AM input for the arbitray output current from the measured AM input for discrete output current.

In the measuring apparatus, the frequency keeps so far fixed during the scanning of the AM input and furthermore during the scanning of the output current. It is easy to see that the frequency may differ from the output current. Letting the frequency of the carrier equal fᵢ for the output current i, scanning the AM input plots the output voltage against the AM input at the frequency of fᵢ. The AM input thus obtained keeps the frequency of the carrier in the neighborhood of fᵢ while the output current of the power supply is i.

It is possible to generate the optimal carrier tracking the shift of the frequency caused by the change of the load. The resonance circuit may vary the resonance frequency dependent on the load, and the frequency of the carrier is capable of tracking the varying resonance frequency caused by the load.

Amplitude Ratio

Since the resonance circuit is a narrow bandpass filter, the carrier fixed in amplitude and modulated in frequency supplied to the resonance circuit changes to the carrier modulated in amplitude at the output of the resonance circuit. As for the carrier supplied to the resonance circuit loaded with a resistor, an amplitude ratio, being the voltage ratio of the input to output carriers, shows resonance characteristics against the frequency of the carrier. The resonance circuit shows a large amplitude ratio at the resonance frequency. The power supply using the resonance circuit makes use of the amplitude ratio for voltage conversion and utilizes frequency dependence of the amplitude ratio for regulation of the output voltage.

In the case that a frequency range of the carrier is selected to be higher than the resonance frequency of the resonance circuit as shown in FIG. 3, lowering the frequency increases the output voltage, and raising the frequency decreases the output voltage, which stabilizes the output voltage. In the case that the frequency range is less than the resonance frequency, raising the frequency increases the output voltage, and lowering the frequency decreases the output voltage.

Plural Resonances

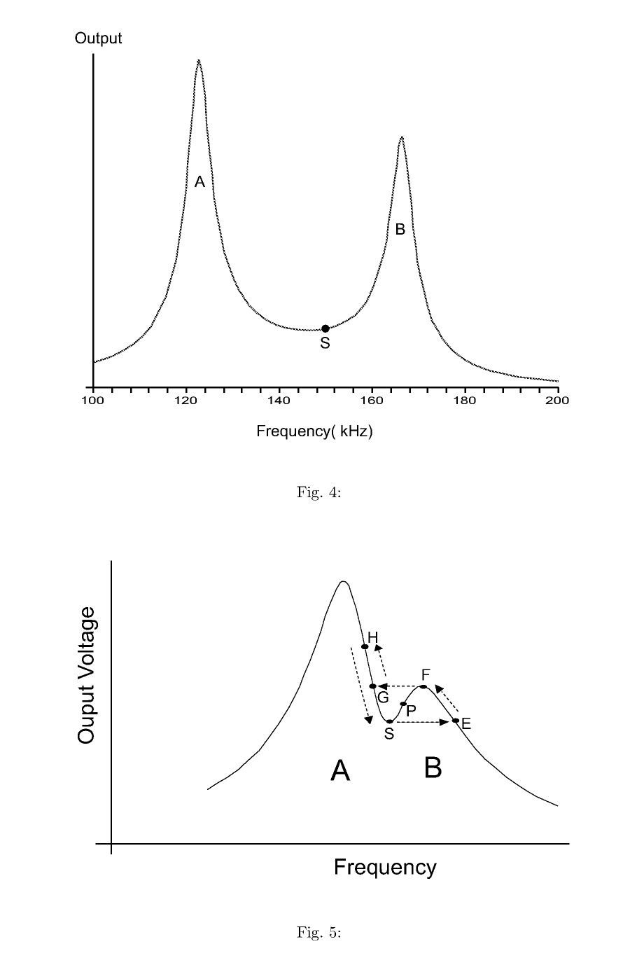

The resonance circuit may have plural resonances. FIG. 4 shows the resonances of the resonance circuit employed in the implementations. The resonance circuit have two resonances named A and B between 100 kHz and 200 KHz, We use the right slope of resonance A for the voltage generation. Climbing the right slope increases the output voltage, and descending the slope decreases the voltage.

Let S be the frequency of the carrier where no feedback is effective. Then S being about 150 kHz,let S=150 kHz be assumed. Let v_{f} be the output of a frequency modulation circuit, the frequency of the carrier is (150-20v_{f}) kHz. In the case the output voltage is less than the reference voltage, the voltage error becomes positive, and the frequency decreases. In the case the output voltage is higher than the reference voltage, the voltage error becomes negative, and the frequency increases. Then while the frequency is on the right slope of A, climbing the slope if the output voltage is less than the reference voltage, and descending the slope if the output voltage is higher than the reference voltage, by which feedback of the voltage error makes the output voltage equal the reference voltage.

As FIG. 5 shows, letting the frequency of the carrier be at P on the left slope of resonance B under accidental circumstances that the output voltage becomes higher than the output voltage, then the feedback makes the frequency climb the slope further. As the frequency climbs the slope, the output voltage becomes higher and then the frequency moves beyond resonance F and finally stays at E on the right slope of B where output voltage equals the reference voltage. Turning on the power supply, the output voltage of the power supply happens to be higher than the reference voltage, which makes the frequency begin to climb the right slope of B.

Power on Sequences

Climbing the right slope of resonance A requires keeping the reference voltage higher than the output voltage on turning on the power supply. It is possible to satisfy the requirement artificially. In most cases, the artificial satisfying disturbs the feedback and makes the voltage error continue large, disabling the output voltage track the reference voltage. The integral part of the voltage error piling up, the feedback stops to work normally. In any way, the time interval for the artificial satisfying is limited. In the following, we keep the amplitude of the carrier held low in a fixed time interval after turning on the power supply, by which the output voltage stays low to satisfy the requirements.

While the output of the frequency modulation circuit is negative, the frequency of the carrier stays on the right slope of resonance B. Keeping the amplitude held low during the FM input being negative, the frequency climbs the right slope of B and jumps to the right slope of A as the reference voltage increases in voltage. When the frequency switches to the slope A, which makes the FM input positive, the carrier increase in amplitude, and then it may happen that the output voltage becomes larger than the reference voltage. In this sense, keeping the amplitude held low during the FM input being negative may cause oscillation. But the oscillation terminates as the reference voltage increases in voltage.

The time delay from the output voltage becoming higher than the reference voltage to the FM input becoming negative is much larger than the time delay where the amplitude of the carrier reflects the input of the amplitude modulation circuit. So the reference voltage growing high to some extent, the FM input keeps positive even though the output voltage becomes higher than the reference voltage so far as the feedback works correctly.

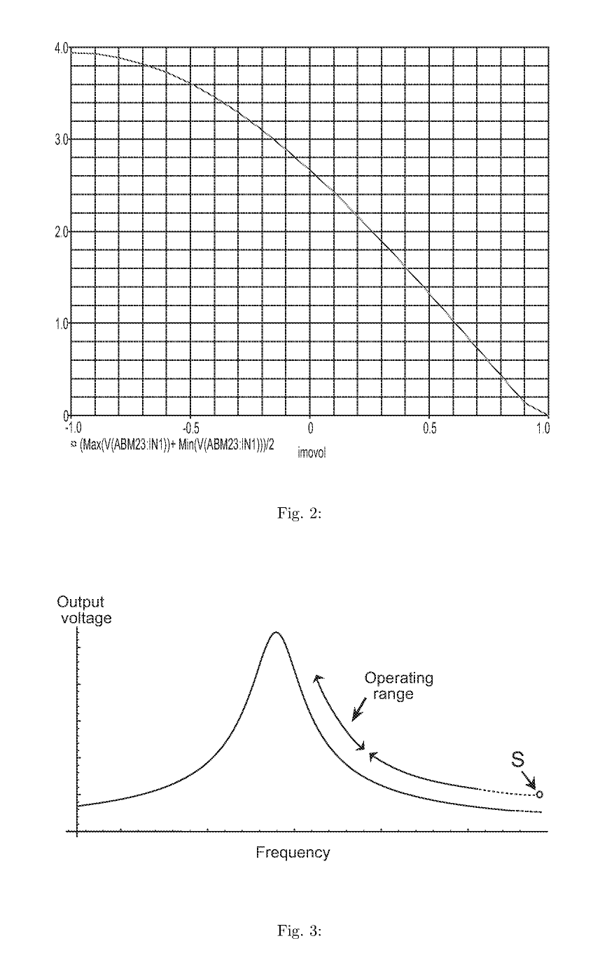

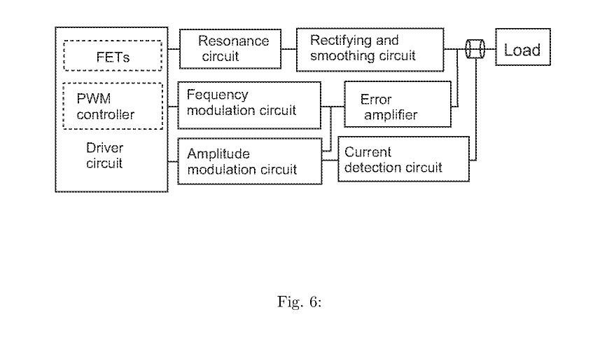

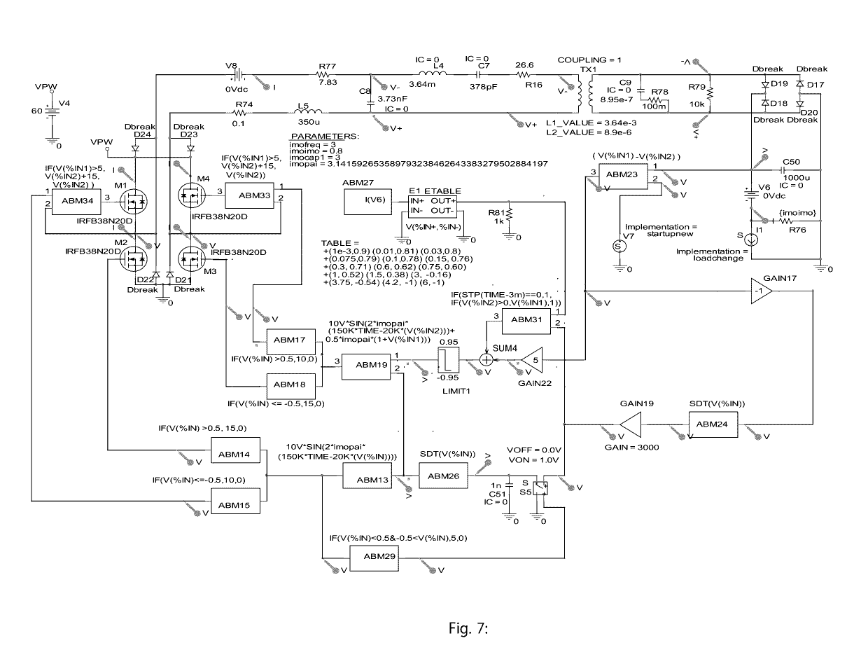

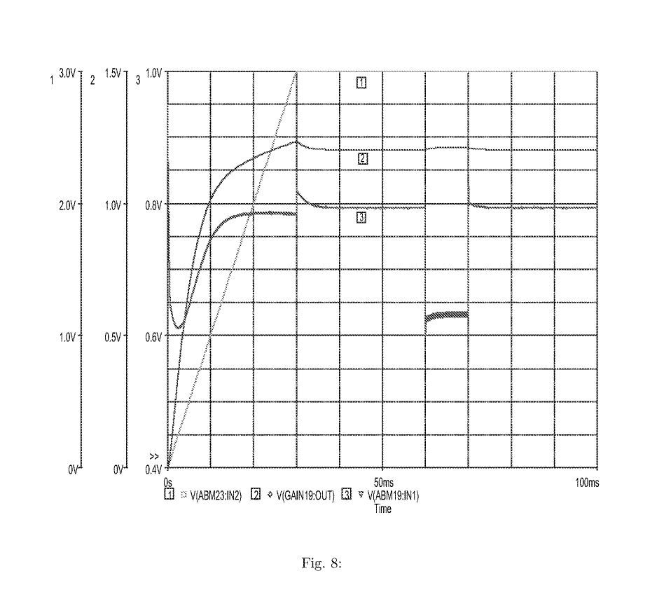

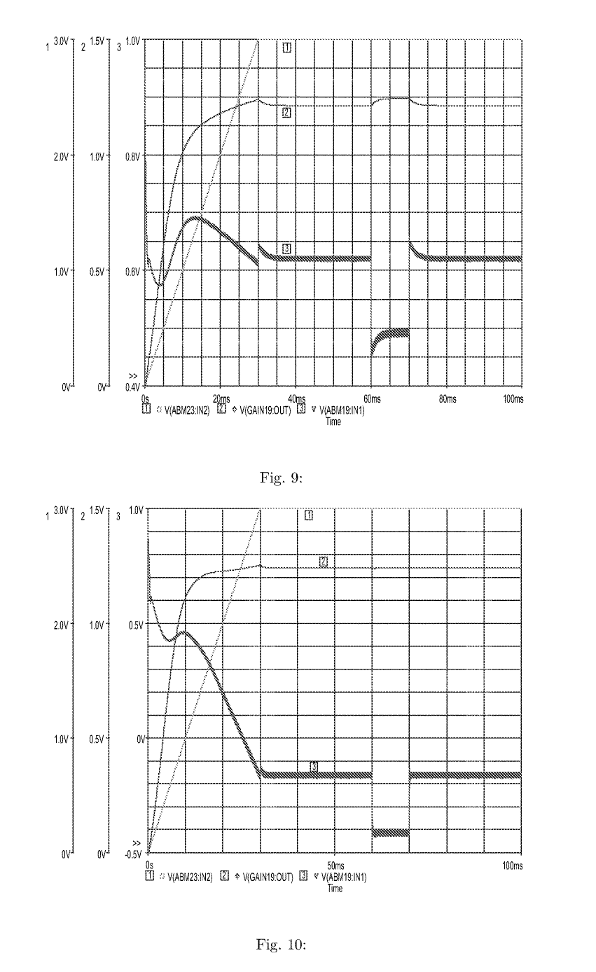

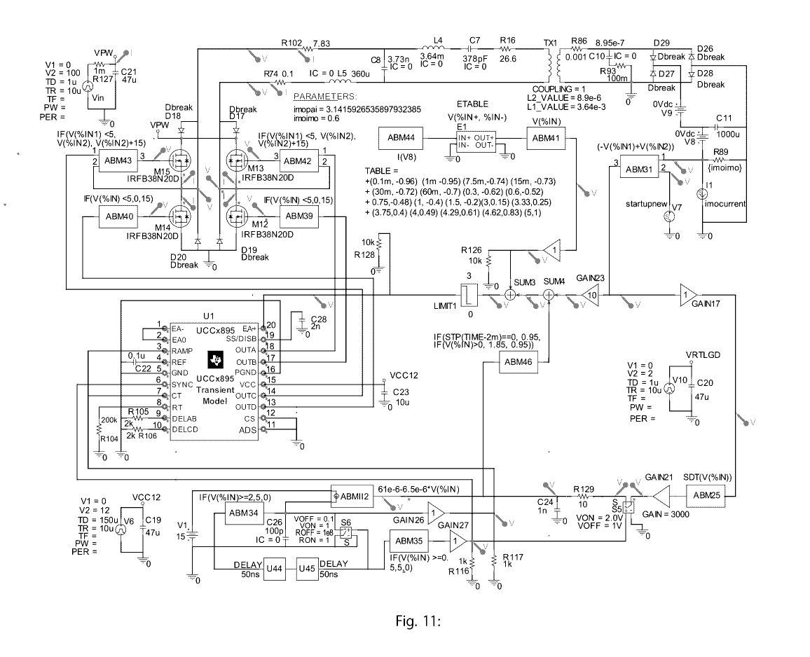

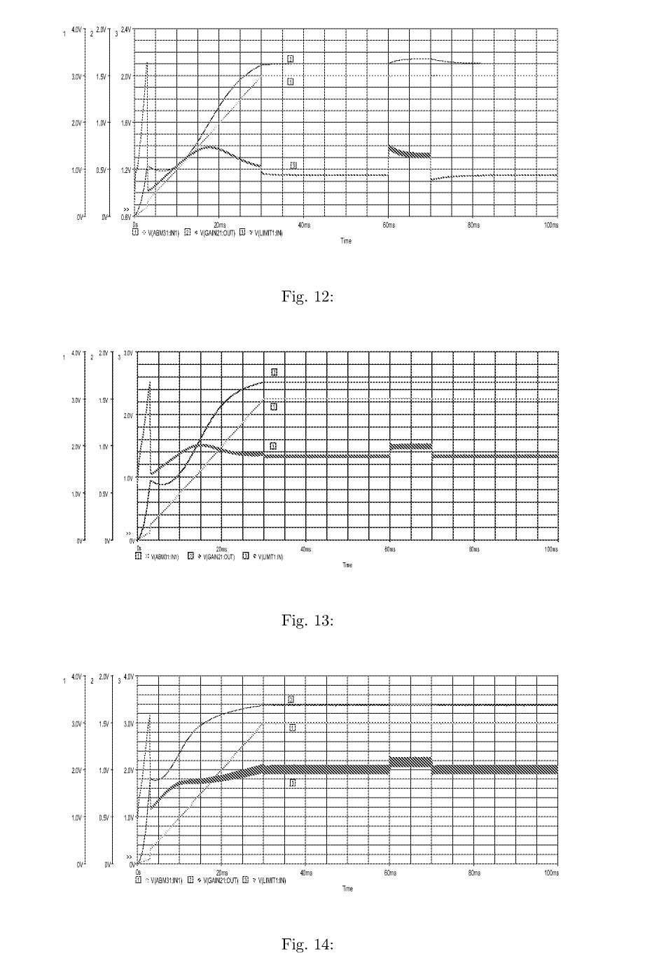

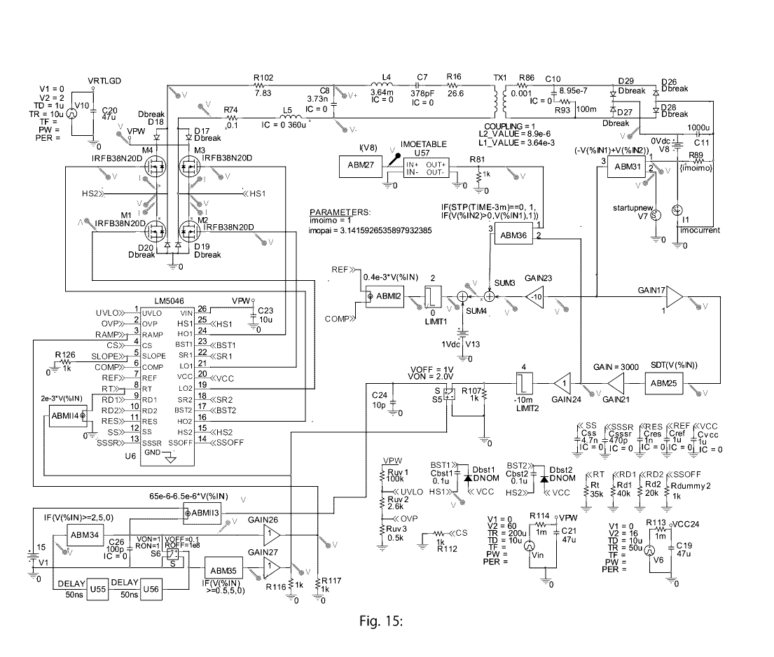

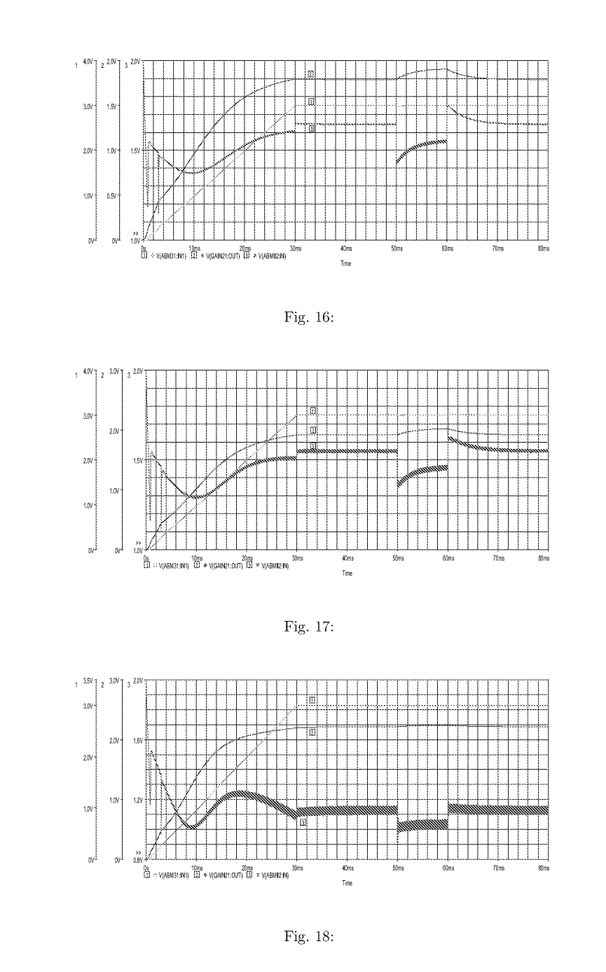

### BRIEF DESCRIPTION OF DRAWINGS

[FIG. 1] Configuration of ideal PMM Controller

[FIG. 2] PLot of output voltage against amplitude of carrier

[FIG. 3] Frequency response of resonance and range of carrier frequency

[FIG. 4] Two resonance of resonance circuit

[FIG. 5] Transition of carrier frequency among resonances

[FIG. 6] Block diagram of stabilized direct-current power supply utilizing resonance circuit

[FIG. 7] Simulation circuit for stabilized direct-current power supply utilizing ideal PWM controller

[FIG. 8] Simulation for load of 50 Ω

[FIG. 9] Simulation for load of 5 Ω

[FIG. 10] Simulation for load of 1 Ω

[FIG. 11] Simulation circuit for stabilized direct-current power supply utilizing UCC3895

[FIG. 12] Simulation for load of 50 Ω

[FIG. 13] Simulation for load of 5 Ω

[FIG. 14] Simulation for load of 1 Ω

[FIG. 15] Simulation circuit for stabilized direct-current power supply utilizing LM5046

[FIG. 16] Simulation for load of 50 Ω

[FIG. 17] Simulation for load of 5 Ω

[FIG. 18] Simulation for load of 1 Ω

### DESCRIPTION OF EMBODIMENTS

Stabilized Direct-Current Power Supply

A block diagram of a stabilized direct-current voltage power supply, using a resonance circuit and composed of a voltage generation circuit and a feedback circuit, is shown in FIG. 6. The voltage generation circuit contains a driver circuit, the resonance circuit, and a rectifying and smoothing circuit. The feedback circuit consists of an error amplifier, a current detection circuit, an amplitude modulation circuit, and a frequency modulation circuit. The driver circuit, supplied with an external direct current voltage supply, generates the high-frequency alternating current modulated both in frequency and amplitude, which is hereafter called carrier. The frequency modulation circuit regulates the frequency of the carrier. The amplitude modulation circuit controls the amplitude of the carrier. The carrier drives the resonance circuit.

The resonance circuit shows resonance. The amplitude of the carrier supplied by the resonance circuit depends on the frequency and amplitude of the carrier supplied to the resonance circuit. The rectifying and smoothing circuit rectifies and smooths the output of the resonance circuit, generating the output voltage of the power supply and supplying the output voltage to the load and to both the error amplifier and the current detection circuit.

The error amplifier compares the output voltage with the reference voltage supplied externally to set up the output voltage, detecting the voltage error and supplying the voltage error to the frequency modulation circuit and the amplitude modulation circuit. The current detection circuit monitors the output current, measuring the output current in magnitude and supplying the output current to the amplitude modulation circuit. Thus the voltage error and the output current is fed back to the frequency and the amplitude of the carrier.

Error Amplifier

The error amplifier detects the voltage error between the output voltage and the reference voltage, supplying the voltage error to the frequency modulation circuit and the amplitude modulation circuit.

Frequency Modulation Circuit

The frequency modulation circuit converts the voltage error for the FM input of the PWM controller. As Patent Documents one and three shows, transfer function providing the pole located in the neighborhood of the zero stabilizes feeding back the voltage error to the frequency. So the frequency modulation circuit converts the voltage error through the transfer function with the pole located in the neighborhood of the origin.

Amplitude Modulation Circuit

The amplitude modulation circuit merges the voltage error and the output current so as to fit the FM input of the PWM controller. The transfer function of the amplitude modulation circuit does not include such the substantial delay caused by an integral part in expression 1. So the feedback to the amplitude is much faster than the feedback to the frequency.

Driver Circuit

The driver circuit driving the resonance circuit includes a full bridge and the PWM controller generating gate pulses turning on and off four FETs in the full bridge. Two half bridges connected in parallel compose the full bridge where the half bridge comprises two FETs connected in a series. A pair of gate pulses drives two FETs in the half bridge, where the gate pulses ate approximately complementary. The full bridge operates in a phase-shift mode, where there is phase shift between the pairs, and the phase shift are under the external control.

The gate pulses turning on and off the FETs are of the same frequency, twice the frequency of the carrier. The FM input of the PWM controller controls the frequency of the gate pulses. There is the phase shift between one pair pf the gate pulses turning on and off one half bridge and the other pair of the gate pulses turning on and off the other half bridge, where the phase shift controls the amplitude of the carrier. The AM input of the PWM controller controls the phase shift of the pairs and then the amplitude of the carrier. The PWM controller generates the gate pulses following the output of the frequency modulation circuit and output of the amplitude modulation circuit.

Resonance Circuit

The resonance circuit shows frequency characteristic and load dependency. The resonance circuit is used in the voltage generation circuit. Let amplitude ratio of the resonance circuit be defined by the ratio of the input to the output in voltage where the output of the resonance circuit is connected to the resistor, the amplitude ratio shows resonance characteristics as a function of the frequency of the carrier. The resonance circuit has input capacitance. The sinusoidal carrier is indispensable to drive the input capacitance efficiently, An inductor resonating with the capacitance generating the approximate sinusoidal carrier, reduces dissipation where the inductor is in a series to the input. The resonance frequency of the inductor and the input capacitance is to be higher than the frequency of the carrier.

The resonance circuit used in the power supply has limitations that its electrical equivalent circuit can not represent. Selecting the range of the freuency for the carrier higher than the resonance circuit avoids the limitations. Then if the output voltage is higher than the reference voltage, the frequency increases moving away from the resonance frequency. In the opposite case, the frequency decreases, moving close to the resonance frequency.

Rectifying and Smoothing Circuit

The output of the resonance circuit modulated in amplitude varies with the frequency and the amplitude of the carrier at the input. The rectifying and smoothing circuit rectifies the output of the resonance circuit to be a direct current voltage by a diode bridge. The output of the diode bridge is buffered by a capacitance. The capacitance reduces the voltage ripples in the output voltage

Current Detection Circuit

The current detection circuit measures an output current, supplying the amplitude modulation circuit with the output current.

### EXAMPLE 1

Simulation Circuit for Ideal PWM Controller

FIG. 1 shows a simulation circuit for the ideal PWM controller, where FM denotes the FM input, AM the AM input, and GA, GB, GC and GD the gate pulses. A circuit element called a behavior model, where a mathematical expression defines the relation between the input and the output of the model, is available for simulation. In the simulation circuit, there are many behavior models, which are identified by label ABM with a sequence number. ABM26, ABM13, ABM14 and ABM15 cooperate to generate rectangular pulses with the frequency specified by the FM input. ABM26 outputs integration of the FM input. ABM13 produces the output defined by [3]

10V*SIN(2*π*(150K*TIME−20K*(V(%/N))))

Then ABM13 generates the sinusoidal wave with the frequency of the FM input. ABM14 and ABM15 digitize the sinusoidal wave with thresholds, generating rectangular pulses that are gate pulses GA and GB driving FETs M1 and M2 respectively in a half bridge.

The combination of ABM19, ABM17 and ABM18 generate the gate pulses driving FETs M3 and M4. ABM19 has input IN1 and IN2 where IN1 is for the FM input. ABM19 produces the output defined by [4]

10V*SIN(2*π*(180K*TIME−20K*(V(%IN2)))+0.5*π*(1+V(%IN1))

where IN1 ranges between −1 and 1. Then the sinusoidal wave defined by expression 3 is delayed in phase against the wave defined by expression B11november15 by [5]

0.5*π*(1+V(%IN1))

Digitizing the sinusoidal wave defined by expression B11november15 with thresholds generates the rectangular pulses which are gate pulses GC and GD driving FETs M3 and M4 in the half bridge. The FM input controls the phase shift between the two pairs of the gate pulses driving the respective half bridges.

### EXAMPLE 2

Simulation Circuit for Stabilized Direct-Current Power Supply

FIG. 7 shows simulation circuit of a direct-current stabilized power supply where the ideal PWM controller simulates an actual PWM controller. In other words, there is a sample & hold circuit. The sample & hold circuit supplied with the output of the frequency modulation circuit provides the output to the FM input, where the output is the output of the frequency modulation circuit sampled by a sample pulse. Digitizing the sinusoidal wave from ABM13 with thresholds generates the sample pulses. The circuit simulating the voltage generation circuit is the faithful reproduction of an actual circuit. Fundamentally in the feedback circuit, the output is linearly related to its input. So in the simulation circuit, the feedback circuit is replaced with simple circuits reproducing the relation between the input and the output. We show the simple simulation circuits for the error amplifier, the frequency modulation circuit, the amplitude modulation circuit, the current detection circuit and the driver circuit that constitutes the feedback circuit

Simulation Circuit for Error Amplifier

Provided with two input and one output terminals, ABM23 implements the error amplifier, where the output is equal to a voltage difference between the input. The output of ABM23 is the voltage error.

Simulation Circuit for Frequency Modulation Circuit

The combination of ABM24, GAIN17 and GAIN19 simulates the frequency modulation circuit where label GAIN with a sequence number identifies gain blocks. ABM24 functions as SDT(·), the output being the integration of the input. GAIN19 provided with the output of ABM24 supplies the output to the FM input. Letting E be the gain of GAIN19, the transfer function of the frequency modulation circuit is given by

$$\frac{E}{s} \qquad [ 6 ]$$

Simulation Circuit for Current Detection Circuit

V6 and ABM27 simulate the current detection circuit, where label V with a sequence number identified voltage sources. The voltage source the output voltage of which is 0 V measures the current flowing through the voltage source. ABM27 outputs the current in voltage.

Simulation Circuit for Amplitude Modulation Circuit

The combination of E1, ABM31, GAIN22, SUM4 and LIMIT1 simulates the amplitude modulation circuit, where label E with a sequence number identifies a lookup table in voltage called ETABLE, label SUM with a sequence number does summing elements, and label LIMIT with a sequence number does limiting elements. The amplitude modulation circuit provided with the voltage error at the input of GAIN22 and the output current at IN+ of E1 supplies the output to the AM input of the PWM controller after the ABM31 stopping climbing the false slope on switching on the power supply outputs its input namely the output of E1 except the power supply being turned on.

A lookup table prepared in E1 converts the output current that the current detection circuit supplies at IN+ of E1, outputting the result to one input of SUM4. SUM4 receiving the output of GAIN22 at the other input combines the voltage error and the output current, summing the both of the input. LIMIT1 supplied with the output of SUM4 limits the range between −1 and 1, the output of LINIT1 meeting with the AM input of the PWM controller.

Simulation Circuit for Driver Circuit

The combination of M1, M2, M3, M4, ABM33, ABM34 and the PWM controller simulates the driver circuit. M1, M2, M3, and M4 simulates FETs constituting the full bridge. AMM33 and ABM34 simulate level converters for FETs at the high side.

### SIMULATION EXAMPLES 1

The simulation circuit in FIG. 7 shows that the feedback implemented in the stabilized direct-current power supply is stable. FIG. 8, FIG. 9 and FIG. 10 shows simulation results for load of 50Ω, 5Ω and 1Ω respectively. In the figure, a horizontal axis shows time, and vertical axes 1, 2 and 3 correspond to the output voltage, the output of the frequency modulation circuit and the output of the amplitude modulation circuit. the output current is added by 600 mA for 100 msec to the stationary output current of 1 A.

### EXAMPLE 3

Simulation Circuit for Stabilized Direct-Current Power Supply Utilizing UCC3895

TEXAS INSTRUMENTS manufactures UCC3895 that is a PWM controller for the carrier of a fixed frequency. UCC3895 is capable of synchronizing with external reset pulses. Reset pulses and sawtooth pulses synchronized with the reset pulses make UCC3895 operate as a PWM controller for the variable frequency carrier. TEXAS INSTRUMENTS provides a spice model simulating UCC3895, where the spice model is ciphered, and details of the model are unknown. FIG. 11 shows the simulation circuit for a stabilized direct-current power supply where the spice model simulates UCC3895 with external synchronization. Comparing the simulation circuits in FIG. 7 and in FIG. 11, + the ideal PWM controller is replaced with UCC3895 and a reset•sawtooth pulse circuit, which accompanies additional modifications to the amplitude modulation circuit. The amplitude modulation circuit supplies its output to the EAP terminal of UCC3895. The frequency modulation circuit provides its output to a frequency modulation input of the reset•sawtooth pulse circuit.

Reset•Sawtooth Pulse Circuit

The reset•sawtooth pulse circuit generates reset pulses and sawtooth pulses. As is shown in FIG. 11, the reset•sawtooth pulse circuit includes the frequency modulation input and a sample & hold circuit. The sample & hold circuit samples and holds the frequency modulation input with the reset pulse until the next reset pulse. The output of the sample & hold circuit is converted to the current so as to charge a capacitor. Then the constant current charges the capacitor in each cycle. The voltage spanning capacitor reaching a predetermined voltage generates the reset pulse that in turn forces the capacitor to be discharged to the ground. The voltage spanning the capacitor is the sawtooth pulses synchronized with the reset pulses.

### SIMULATION EAMPLES

The simulation circuit in FIG. 11 shows that the feedback implemented in the stabilized direct-current power supply is stable. FIG. 12, FIG. 13 and FIG. 14 shows simulation results for load of 50 Ω, 5 Ω and 1 Ω respectively. In the figure, a horizontal axis shows time, and vertical axes 1, 2 and 3 correspond to the output voltage (ABM31:IN1), the output of the frequency modulation circuit (GAIN21:OUT) and the output of the amplitude modulation circuit (LIMIT1:IN).

### EXAMPLE 4

Simulation Circuit for Stabilized Direct-Current Power Supply Utilizing LM5046

National Semiconductor manufactures LM5046 that is a PWM controller for the carrier of a fixed frequency. LM5046 is capable of synchronizing with external reset pulses. Reset pulses and sawtooth pulses synchronized with the reset pulses make LM5046 operate as a PWM controller for the variable frequency carrier.

National Semiconductor provides a spice model simulating LM5046. The spice model does not implement external synchronization. So we make a patch to the code of the spice model so as to simulate the external synchronization. The version of the spice model is;

| | |
|---|---|
| * Model Number | : LM5046 Phase-Shift Full Bridge PWM |

Controller with Integrated MOSFET Drivers

| | |
|---|---|
| * Last Revision Date | : February 25, 2011 |
| * Revision Number | : 1.1 |

The patch is;

| | |
|---|---|
| Eleb2 | LEB5 0 LEB6 0 1 |

| | |
|---|---|
| Emsk1 | MSK4 0 VALUE { if(V(CLK)<=2.5 & V(PWM)<=2.5,5,0) } |
| Emsk2 | MSK5 0 VALUE { if (V(PWM)>2.5 & V(CLK)<=2.5,5,0) } |

| | |
|---|---|
| Eosc1 | OSC1 0 VALUE { if(V(OSC2)>cos(2*3.14*50E−9/(2/ |

(6.25E9*I(VRT))+110E−9)),5,0) }

| | |
|---|---|
| Eosc2 | OSC3 0 VALUE { if (V(VREFuv)<=2.5 & V(VCCuv)<=2.5 |

& V(FAULT)<=2.5,sin(2*3.141592*TIME*I(VRT)/100E−12/2),0) }

| | |
|---|---|
| Eosc3 | NCLK 0 VALUE { {5−V(CLK)} } |

| | |
|---|---|
| Eleb2 | LEB5 0 LEB6 0 1 |

| | |
|---|---|
| Emsk1 | MSK4 0 VALUE { if(V(CLK)<=2.5 & V(PWM)<=2.5,5,0) } |
| Emsk2 | MSK5 0 VALUE { if(V(PWM)>2.5 & V(CLK)<=2.5,5,0) } |

*******************************************************************************

| | |
|---|---|
| *Eosc1 | OSC1 0 VALUE { if(V(OSC2)>cos(2*3.14*50E−9/(2/ |

(6.25E9*I(VRT))+110E−9)),5,0) }

| | |
|---|---|
| *Eosc2 | OSC3 0 VALUE { if(V(VREFuv)<=2.5 & V(VCCuv)<=2.5 |

& V(FAULT)<=2.5,sin(2*3.141592*TIME*I(VRT)/100E−12/2),0) }

*******************************************************************************

| | |
|---|---|
| Eosc1 | OSC1 0 VALUE { if(I(VRT)>5e−3V & V(OSC3)>=2.5,5,0) } |
| Eosc2 | OSC3 0 VALUE { if(V(VREFuv)<=2.5 & V(VCCuv)<=2.5 |

& V(FAULT)<=2.5,5,0) }

| | |
|---|---|
| Eosc3 | NCLK 0 VALUE { {5−V(CLK)} } |

FIG. 15 shows a simulation circuit for a stabilized direct-current power supply where LM5046 with the patch is employed as a PWM controller for a variable frequency carrier. The simulation circuit utilizes a lookup table defined as follows.

*
.SUBCKT imoEtable IN+ IN− OUT+ OUT−
E1 OUT+ OUT− TABLE {V(IN+,IN−)}=(
+(7.5m,660m)
+(30m,650m)
+(60m,645m)
+(150m,610m)
+(300m,600m)
+(600m,550m)
+(750m,520m)
*(1.0,490m)
+(1.5,400m)
*(3.0,130m)
*(3.333,95m)
*(3.75,10m)
*(4.28,−90m)
+(5.0,−230m)
+(6.0,−450m)
*(7.5,−930m)
+)
.ENDS imoEtable
*

Comparing the simulation circuits in FIG. 7 and in FIG. 15, + the ideal PWM controller is replaced with LM5046 and the reset sawtooth pulse circuit, which accompanies additional modifications to the amplitude modulation circuit. The amplitude modulation circuit supplies its output to the COMP terminal of LM5046. The frequency modulation circuit provides its output to the frequency modulation input of the reset sawtooth pulse circuit.

Reset•Sawtooth Pulse Circuit

The reset•sawtooth pulse circuit is same with the one in FIG. 11.

### SIMULATION EAMPLES

The simulation circuit in FIG. 15 shows that the feedback implemented in the stabilized direct-current power supply is stable. FIG. 16, FIG. 17 and FIG. 18 shows simulation results for load of 50 Ω, 5 Ω and 1 Ω respectively. In the figure, a horizontal axis shows time, and vertical axes 1, 2 and 3 correspond to the output voltage (ABM31:IN1), the output of the frequency modulation circuit (GAIN21:OUT) and the output of the amplitude modulation circuit.

### INDUSTRIAL APPLICABILITY

Rectifying and smoothing the output of a resonance circuit to produce the output1 of the power supply, the carrier driving the resonance circuit being modulated both in frequency and amplitude makes the resonance circuit driven with the carrier of such the frequency that is optimal for the output current namely the load. The modulation of the carrier also makes it possible to implement an efficient power supply with resonance circuits ranging from the widely employed resonance circuit of a low Q value to the resonance circuit of a high Q value where the resonance frequency is dependent on the load

1. A pulse width modulation (hereafter abbreviated to PWM) controller
having
1. both frquency modulation input and amplitude modulation input,
2. a sawtooth voltage V_{T} between a predetermined voltage V_{L} and a predetermined voltage V_{H} where V_{L} i V_{H}, and
3. a sample pulse:
wherein
1. synchronized with the negation of a sample pulse, a sawtooth voltage begins to rise from V_{L} to V_{H} at a slope defined by the value of the frequency modulation input sampled by the sample pulse
2. the sample pulse is asserted when the sawtooth voltage reaches V_{H}, and
3. the sawtooth voltage returns to V_{L} while the sample pulse is asserted:
generating the output of the PWM controller based on the pulses produced by comparing the amplitude modulation input and the sawtooth voltage V_{T} together with the sample pulse.

2. A power supply
including
1. a driver circuit,
2. a resonance circuit,
3. a rectification and smoothing circuit,
4. a reference voltage
5. an error amplifier,
6. a current detection circuit,
7. a frequency modulation circuit, and
8. an amplitude modulation circuit:
wherein
1. the driver circuit including the PWM controller descrined in claim 1 generates a carrier which is supplied to the resonance circuit, the carrier being modulated in frequency and in amplitude,
2. the resonance circuit converts the frequency-modulated carrier at the input to an amplitude-modulated carrier at the output,
3. the rectification and smoothing circuit rectifies the amplitude-modulated carrier supplied by the resonance circuit to a direct-current output voltage of the power supply,
4. the reference voltage is externally supplied to set up the output voltage of the power supply
5. the error amplifier outputs the voltage difference between the output voltage and the reference voltage to both the frequency modulation circuit and the amplitude modulation circuit, the voltage difference being called an error voltage hereafter,
6. the current detection circuit measures the output current of the power supply and converts the output current so as to be supplied to the amplitude modulation circuit,
7. the frequency modulation circuit transforms the error voltage provided by the error amplifier so as to be supplied to the frequency modulation input of the PWM controller, and
8. the amplitude modulation circuit combines the output of the error amplifier and the current detection circuit so as to be supplied to the amplitude modulation input of the PWM controller:
being stabilized by the frequency modulation circuit output of which includes the integral of the error voltage.

3. The power supply described in claim 2
including
the current detection circuit supplying a current equivalent corresponding to the measured output current,
where
the amplitud modulation input of the PWM controller being provided with the current equivqlent, the driver circuit generates the carrier of such the amplitude that restores the output current if the carrier is at the predetermined frequency:
making the power supply providing the output current by the carrier at the predetermined frequency corresponding to the output current.

4. The power supply described in claim 3
including
the amplitude modulation circuit the output of which is supplied to the amplitude modulation input of the PWM controller:
where
the amplitude modulation circuit outputs the sum of the proportional of the error voltage provided by the error amplifier and the current equivalent supplied by the current detection circuit.

5. In the power supply described in claim 1
having
1. the resonance citcuit with plural resonances,
2. the frequency of the carrier without the feedback of frequency modulation being located at the bottom of the valley between the two resonances, and
3. the frequency range of the carrier being covered by one side of the correct slope of the valley:
the amplitude of the carrier being reduced while the frequency of the carrier belongs to the other side of the false slope,
which makes the frequency of the carrier moves to the correct slope, and protects the feedback against the accidental occurence that the turning on the power supply happens to make the frequency climb the false slope.
